(19) United States
(12) Patent Application Publication
(10) Pub. No.: US 2008/0093699 A1
(43) Pub. Date: Apr. 24, 2008

(54) SEMICONDUCTOR DEVICE AND METHOD OF MANUFACTURING THE SAME

(75) Inventors: Tomohisa ABE, Kanagawa (JP); Gen Tsutsui, Kanagawa (JP); Tadashi Fukase, Kanagawa (JP); Yasushi Nakahara, Kanagawa (JP); Kiyotaka Imai, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/874,221

(22) Filed: Oct. 18, 2007

(30) Foreign Application Priority Data
Oct. 18, 2006 (JP) 2006-283961

(51) Int. Cl. H01L 29/00

(52) U.S. Cl. 257/499

(57) ABSTRACT

The semiconductor device includes a plurality of transistors at least having different channel widths from each other. Threshold voltages of those transistors are set to be substantially equal to each other, by using both of substantially the same channel dose for each of those transistors, and work function control using a predetermined metal to be deposited on a gate insulating of those transistors and/or a gate electrode material of each of those transistors (that is, work function control based on a gate structure (gate insulating film and/or gate electrode) with respect to a channel region of each of those transistors).

### BACKGROUND OF THE INVENTION

1. Field of the Invention

The present invention relates to a system-on-a-chip (SoC) semiconductor device, and a method of manufacturing the same. In particular, the present invention relates to threshold voltage control for transistors provided on an SoC.

2. Description of the Related Art

A threshold voltage of a transistor has a considerable effect on electrical characteristics such as an operating speed and a leak current. Accordingly, it is necessary to set the threshold voltage so as to obtain desired characteristics. The threshold voltage of a transistor depends on an impurity concentration of a channel region. Therefore, by controlling an amount of impurities to be doped into the channel region (channel dose), it is possible to control the threshold voltage (for example, see JP 2001-267431 A). JP 2001-267431 A also discloses that controlling of a planar shape of a portion to be doped with impurities while setting the channel dose to be constant enables adjustment of the threshold voltage. However, in the case of controlling the threshold voltage depending only on the control of the channel dose and the doped portion, it is necessary to increase the dose to some extent. As a result, problems such as decrease of a carrier mobility and increase of a junction leak current remain unsolved.

In view of the above, JP 2006-093670 A discloses a technology of controlling the threshold voltage based on not only the channel dose, but also a function of a specific metal deposited on an interface between a gate insulating film and a gate electrode. With the method, the amount of the impurities to be doped into the channel region can be reduced. Accordingly, the method is more excellent than the method as disclosed in JP 2001-267431 A.

The present inventors have recognized as follows. In an SoC semiconductor device, a plurality of functional blocks such as a logic functional block, a memory functional block such as an SRAM or a DRAM, and an I/O buffer block are formed in a coexisting manner. Transistors constituting those functional blocks generally have different dimensions and shapes (channel width and length, or gate insulating film thickness). For example, it is necessary for a so-called I/O transistor constituting an I/O buffer to have a relatively high resistance to high voltage. Accordingly, the channel length of the I/O transistor is relatively long and the gate insulating film thereof is thicker than that of the transistor constituting the logic functional block. On the other hand, with regard to the memory functional block, there is a strong demand for miniaturization so as to obtain a required storage capacity. As a result, the memory transistor is formed with a considerably small channel width as compared to the I/O transistor and the logical transistor. Thus, the dimensions and the shapes of the transistors are different from each other depending on the functional blocks in which they are included in many cases. However, also in this case, it is necessary for transistors which operate at the same power supply voltage (operating voltage) to have threshold voltages set to be substantially equal to each other.

On the other hand, also in transistors in the same functional blocks (that is, also in transistors having the same dimensions and shapes), or also in the transistors which operate at the same power supply voltage, a plurality of transistors having different threshold voltages are required. For example, even when the channel lengths and widths, and the gate insulating film thicknesses of the transistors constituting a logic functional block are substantially equal to each other, it is necessary for transistors required for high-speed operation to have a low threshold voltage, and it is necessary for transistors which place a high priority on a low leak current to have a high threshold voltage. Transistors having an intermediate threshold voltage therebetween are also present. In the memory functional block and the I/O buffer, a plurality of kinds of threshold voltages are required.

Thus, in the SoC semiconductor device, there are provided not only a plurality of transistors having threshold voltages substantially different from each other, but also transistors required to have substantially the same threshold voltage irrespective of a difference in channel width and length.

The threshold voltage controlling method as disclosed in JP 2006-093670 A is excellent in that the channel dose can be reduced, but does not involve threshold control with respect to transistors used in an SoC semiconductor device, in particular, with respect to transistors having different channel widths.

### SUMMARY

According to the present invention, there is provided a semiconductor device comprising a plurality of transistors each at least having a different channel width from each other, in which the plurality of transistors have threshold voltages which are set to be substantially same values each other by use of substantially the same channel dose for each of the plurality of transistors, and work function control using a predetermined metal to be deposited on a gate insulating of those transistors and/or a gate electrode material of each of those transistors (that is, work function control based on a gate structure (gate insulating film and/or gate electrode) with respect to a channel region of each of the plurality of transistors). Note that, when a difference between the threshold voltages of the plurality of transistors is equal to or less than 0.03 V, it can be regarded that the transistors are set to substantially the same threshold voltage.

In the present invention, the channel doses for the plurality of transistors each having a different channel width are set to be substantially equal to each other. This is based on the knowledge that, when the channel dose is set within a predetermined range, adjustment of the threshold voltage can be performed almost independently of the change in channel width.

Specifically, FIGS. 1A and 1B each show the shift of the threshold voltage with respect to the channel dose when the channel width W is used as a parameter in a MOS transistor having a gate insulating film thickness of 2.0 nm and a gate length of 50 nm (FIG. 1A shows a case of an N-channel transistor and FIG. 1B shows a case of a P-channel transistor). Note that the N-channel transistor is formed in a P-well region, and the P-channel transistor is formed in an N-well region. The impurity concentration of each of the well regions is set to be extremely low in consideration of a junction capacitance and a resistance to high voltage with respect to a substrate on which the transistors are formed. Accordingly, with regard to the threshold voltage of each of the transistors, the channel dose is predominant.

As apparent from FIGS. 1A and 1B, in a case of the N-channel transistor, when the channel dose is equal to or less than 7×10¹² (atoms/cm²), fluctuation of the threshold voltage in the SoC transistor is equal to or less than 0.03 V with a channel width being in a range from 5 μm to 0.15 μm. On the other hand, in a case of the P-channel transistor, when the channel dose is equal to or less than 1.3×10¹² (atoms/cm²), fluctuation of the threshold voltage in the transistor to be used in the SoC is equal to or less than 0.03 V with a channel width being in a range from 5 μm to 0.15 μm.

On the other hand, the threshold voltage fluctuation of the transistors based on the work function control using a predetermined metal to be deposited on a gate insulating film and/or a gate electrode material of each of the transistors mostly depend on the quantity of the metal to be deposited and the gate electrode material. FIG. 2 shows increase amounts of threshold voltages of an N-channel transistor and a P-channel transistor with respect to the quantity of hafnium deposited on a gate insulating film made of SiON, with the work function control using a predetermined metal to be deposited on the gate insulating film. As apparent from FIG. 2, the threshold voltage is increased as the quantity of hafnium to be deposited becomes larger, and a difference between the threshold voltages of the N-channel transistor and the P-channel transistor becomes larger. It is desirable that the threshold voltages of both the channel transistors be equal to each other as much as possible, so a small quantity of hafnium is preferably used. It is desirable that a difference between a threshold voltage absolute value of the P-channel transistor and a threshold voltage of the N-channel transistor be equal to or smaller than 0.1 V. Accordingly, it is preferable that the deposited quantity of hafnium be set to be equal to or smaller than 1.3×10¹⁴ (atoms/cm²). In this case, the increase amount of the threshold voltage of the N-channel transistor is about 0.12V, and that of the P-channel transistor is 0.22 V.

On the other hand, the increase amount of the threshold voltage becomes smaller as the deposited quantity of hafnium is reduced. Accordingly, in order to obtain a desired threshold voltage, it is necessary to increase the channel dose correspondingly. However, the difference between the threshold voltages of the transistors exceeds 0.03 V in this case. FIGS. 1A and 1B each show the channel dose of this case. However, as described later, it has turned out that there is an effect in that the range of the channel dose for obtaining the threshold voltage difference of equal to or less than 0.03V, can be increased by deposition of hafnium. The channel dose can be increased to 1.1×10¹³ (atoms/cm²) in the case of the N-channel transistor, and can be increased to 1.4×10¹³ (atoms/cm²) in the case of the P-channel transistor. As apparent from FIGS. 1A and 1B, the threshold voltage with that channel dose is about a little smaller than 0.4 V. In any case, the lower limit of the deposited quantity of hafnium is determined in combination of the threshold voltage necessary for each transistor and the channel dose for obtaining the threshold voltage difference equal to or less than 0.03 V. As a rough guide, it is desirable to set the lower limit of the deposited quantity of hafnium to 4×10¹³ (atoms/cm²) with which the effect of the increase of the threshold voltage due to deposition of hafnium is made clear. With this deposited quantity, the increase amount of the threshold voltage of 0.06 V can be obtained in the N-channel transistor and that of 0.1 V can be obtained in the P-channel transistor.

Here, in a MOS transistor having a gate insulating film thickness of 2.0 nm, a gate length of 50 nm, and a transistor width (channel width) of 0.5 μm, when it is assumed that a target threshold voltage is 0.39V, in order to set the threshold voltage only by using the channel dose according to the conventional art, it is necessary to implant boron of 1×10¹³ (atoms/cm²) into the N-channel transistor and to implant arsenic of 1.6×10¹³ (atoms/cm²) into the P-channel transistor.

On the other hand, in the case of using the work function control using hafnium to be deposited on the gate insulating film as in the present invention, as described above, the channel dose (that is, channel impurity concentration) can be reduced. For example, in a case where the deposited quantity of hafnium is set to 1.0×10¹⁴ (atoms/cm²) so that the variation of the threshold voltage obtained by the work function control using hafnium is 0.11 V in the case of the N-channel transistor, and is −0.18 V in the case of the P-channel transistor, when the channel dose for the N-channel transistor is set to 5.3×10¹² (atoms/cm²) and the threshold voltage associated with the channel dose is set to 0.28 V, an effective threshold voltage of the N-channel transistor of 0.39 V (=0.11+0.28) is obtained. Further, when the channel dose for the P-channel transistor is set to 5.5×10¹²(atoms/cm²) and the threshold voltage associated with the channel dose is set to −0.21 V, an effective threshold voltage of the P-channel transistor of −0.39 V (=(−0.18)+(−0.21)) is obtained.

It should be noted herein that, in the case of performing the threshold voltage control only by using the channel impurity, that is, in the case of implanting born of 1×10¹³ (atoms/cm²) in the N-channel transistor, the threshold voltage difference in the channel width range from 5 μm to 0.15 μm is increased to 0.04 V. The implanted channel impurity, that is, boron is absorbed by an inner wall oxide film obtained by shallow trench isolation. Accordingly, there occurs a phenomenon that the impurity concentration is reduced as a transistor width W becomes narrower, which lowers the threshold voltage (this phenomenon is referred to “reverse narrow channel effect”), and as the channel dose becomes larger, the reverse narrow channel effect becomes remarkable, which increases the threshold voltage difference. As a result, in the case of the N-channel transistor, as described above, it is necessary to set the channel dose to 7×10¹² (atoms/cm²) or less so that the threshold voltage difference in the channel width range from 5 μm to 0.15 μm is equal to or smaller than 0.03 V. However, in this condition, the threshold voltage becomes lower than the desired one. In the case where the channel width is in the range from 5 μm to 0.15 μm and the threshold voltage difference is increased to 0.04 V, a difference between a threshold voltage of a core transistor having a channel width in a range from about 5 μm to 0.5 μm and a threshold voltage of an SPAM cell transistor having a channel width of about 0.15 μm is large. Accordingly, it is necessary to divide a channel implantation process so that the threshold values of the core transistor and the SRAM cell transistor are each set to 0.39 V.

On the other hand, in the case of using the work function control using hafnium, the channel dose can be reduced to 5.3×10¹² (atoms/cm²), thereby making it possible to reduce the threshold difference in association with the transistor width W due to the reverse narrow channel effect.

FIG. 3 shows shifts of the threshold voltages of N-channel transistors having the transistor widths W of 1 μm, 0.5 μm, and 0.15 μm, respectively, which are plotted with respect to the deposited quantity of hafnium (channel boron dose is 1×10¹³ (atoms/cm²)), when a threshold voltage with the transistor width W of 5 μm is set as a reference. As a result, it has been found that, even in a case where the channel dose is set to be constant, the reverse narrow channel effect is alleviated when the deposited quantity of hafnium is increased.

FIGS. 4A and 4B each show a shift of a threshold voltage with respect to a channel dose when a transistor width is used as a parameter in case that a deposited quantity of hafnium is set to 1×10¹⁴ (atoms/cm²) (FIG. 4A shows a case of an N-channel transistor, and FIG. 4B shows a case of a P-channel transistor). Due to an effect of alleviating the reverse narrow channel effect by deposition of hafnium, a threshold voltage difference between the transistor having the transistor width W of 5 μm and the transistor having the transistor width W of 0.15 μm becomes smaller even with the same channel dose, as compared with the graphs (FIGS. 1A and 1B) each showing the shift of the threshold voltage only by the channel impurity according to the related art. As a result, when the channel dose in the case of the N-channel transistor is equal to or less than 1.1×10¹³ (atmos/cm²), the channel dose in the case of the P-channel transistor is equal to or less than 1.4×10¹³ (atmos/cm²), the fluctuation of the threshold voltage of transistor to be used in the SoC is equal to or smaller than 0.03 V with the transistor width W being in the range from 5 μm to 0.15 μm, therefore the available range of the channel dose is increased.

Due to two effects of suppressing the reverse narrow channel effect obtained by the work function control using hafnium, that is, an effect of suppressing the reverse narrow channel effect by reducing the channel dose by utilizing the threshold voltage increase using hafnium, and an effect of alleviating the reverse narrow channel effect by deposition of hafnium, the threshold voltage difference between the transistor having the transistor width W of 5 μm and the transistor having the transistor width W of 0.15 μm which are used in the SoC can be reduced to a large extent.

Thus, a plurality of transistors required to have the threshold voltage of 0.39 V can be formed at the same time even when the transistors each have a difference channel width (transistor channel), thereby making it possible to realize reduction of a manufacturing process.

As described above, the SoC includes as, in particular, the I/O transistor, a transistor having a gate insulating film larger than that of each of the logic transistor and the memory transistor. The gate insulating film is thick because the operating voltage is as relatively high as 1.8 V or 3.3 V, and a high withstanding voltage is required. A necessary threshold voltage is about 0.5 V. In the transistor, because of the large thickness of the gate insulating film, the threshold voltage is correspondingly increased.

FIGS. 5A and 5B each show a shift of a threshold voltage with respect to a channel dose in a case where a gate insulating film is used as a parameter (FIG. 5A shows a case of an N-channel transistor, and FIG. 5B shows a case of a P-channel transistor). For example, when it is assumed that a threshold voltage of a core transistor having a gate oxide film thickness of 2.0 nm is 0.39 V, it is necessary to implant boron of 1×10¹³ (atoms/cm²) into the N-channel transistor, and to implant arsenic of 1.6×10¹³ (atoms/cm²) into the P-channel transistor. In this case, when the same channel dose is employed for an I/O transistor which has a gate oxide film thickness of 3.0 nm and is used at a power supply voltage of 1.8 V, the threshold voltage of the N-channel transistor is 0.56 V and the threshold voltage of the P-channel transistor is −0.62 V, which are extremely higher than the necessary threshold voltage. This is because, with the increase of the channel dose, the threshold voltage difference between the transistor having the gate insulating film thickness of 2.0 nm and the transistor having the gate insulating film thickness of 3.0 nm is increased.

FIGS. 6A and 6B each show a shift of a threshold voltage with respect to a channel dose with a gate insulating film being used as a parameter when a deposited quantity of hafnium is set to 1×10¹⁴ (atoms/cm²) (FIG. 6A shows a case of an N-channel transistor, and FIG. 6B shows a case of a P-channel transistor). When it is assumed that a threshold voltage of a core transistor having a gate oxide film thickness of 2.0 nm is 0.39 V, it is sufficient to implant boron of 5.3×10¹² (atoms/cm²) into the N-channel transistor, and to implant arsenic of 5.5×10¹² (atoms/cm²) into the P-channel transistor. When the same channel dose is employed for an I/O transistor which has a gate oxide film thickness of 3.0 nm and is used at a power supply voltage of 1.8 V, the desired threshold voltage values, that is, the threshold voltage of the N-channel transistor of 0.50 V and the threshold voltage of the P-channel transistor of −0.50 V, can be obtained. This is because, by using the work function control using hafnium, it is possible to employ the channel dose with the range in which the difference between the threshold voltage of the transistor having the gate insulating film thickness of 2.0 nm and the threshold voltage of the transistor having the gate insulating film thickness of 3.0 nm can be reduced.

The threshold voltage of the transistor can be increased also by changing the gate electrode material itself from a generally-used polysilicon to a metal (including a so-called full silicide gate electrode in which a silicon gate electrode is substantially fully silicided). In addition, the threshold voltage control may be performed using the work function control by the combination of the predetermined metal to be deposited on the gate insulating film and the full silicide gate electrode.

As described above, by controlling the threshold voltage of the transistor using both of the predetermined channel dose for each transistor, and the threshold voltage increase using the work function control based on the gate structure with respect to a channel region (that is, threshold voltage increase by work function control using deposition of the predetermined metal on the gate insulating film of each transistor and/or the gate electrode material of each transistor), the threshold voltages of the transistors can be set to be substantially equal to each other even when the transistors each have a different channel width and/or a different channel length. In addition, settings of different threshold voltages with respect to the transistors having substantially the same structure, and reduction in number of processes for controlling the threshold voltage with respect to the transistors having different threshold voltages based on the difference of the gate insulating film can be realized.

The channel implantation is performed with the predetermined dose for each transistor having substantially the same threshold voltage, so the impurity concentration and the distribution of the channel region are substantially the same. Accordingly, gate induced drain leakage (GIDL) characteristics of those transistors (GIDL characteristics with respect to a transistor is defined as drain leak current characteristics in association with the voltage shift between the source and the drain of the transistor under the threshold voltage of the transistor) are substantially equal to each other. Specifically, the present invention is also characterized in that a plurality of transistors, at least one of the channel width and the channel length of which is different from each other, are subjected to the work function control using the predetermined metal to be deposited on the gate insulating film and/or the gate electrode material, and the GIDL characteristics of those transistors are substantially equal to each other.

Further, according to the present invention, there is provided a method of manufacturing a semiconductor device including a plurality of transistors each having a different channel width, the method of manufacturing a semiconductor device including: implanting impurities into a channel region of each of the plurality of transistors with substantially the same quantity; and forming a gate structure for each of the plurality of transistors so as to fulfill threshold voltage control using work function control with respect to the channel region of each of the plurality of transistors (gate structure in which a silicon gate electrode is formed by depositing a predetermined metal on the gate insulating film of each of the plurality of transistors and/or a metal gate electrode (including a full silicide gate electrode) is formed on the gate insulating film of each of the plurality of transistors), to thereby form the plurality of transistors.

In a semiconductor device including transistors each having a different gate insulating film thickness, impurities may be implanted also in the channel region of each of the transistors with the same quantity to form a gate insulating film having a desired thickness, and a threshold voltage increasing process using the above-mentioned work function control may be performed.

Further, in a semiconductor device including transistors each having substantially the same channel width and the same channel length as those of at least one of the plurality of transistors and having a different threshold voltage, an impurity implantation amount for the channel region of the transistor may be changed and the threshold voltage increasing process using the above-mentioned work function control may be performed.

As described above, according to the present invention, threshold voltages of a plurality of transistors, at least one of the channel width and the channel length of which is different from each other, can be set to be substantially equal to each other while the number of manufacturing processes can be reduced.

In addition, since the channel dose is suppressed to be small, undesired degradation of characteristics, such as, reduction in carrier mobility and increase of junction leak can be prevented.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are graphs each showing channel dose dependence of a threshold voltage (with a transistor width W being used as a parameter) in a case where work function control using hafnium is not performed;

FIG. 2 is a graph showing increase amounts of threshold voltages of transistors with respect to a quantity of hafnium deposited on a gate insulating film;

FIG. 3 is a graph showing a variation of a threshold voltage of a transistor (when a threshold voltage of a transistor having a width W of 5 μm is set as a reference) with respect to a deposited quantity of hafnium;

FIGS. 4A and 4B are graphs each showing a shift of a threshold voltage (with the transistor width W being used as a parameter) with respect to a channel dose in a case where the deposited quantity of hafnium is 1×10¹⁴ [atoms/cm²];

FIGS. 5A and 5B are graphs each showing a channel dose dependence of a threshold voltage (when a gate insulating film thickness is used as a parameter) in a case where the work function control using hafnium is not performed;

FIGS. 6A and 6B are graphs each showing a channel dose dependence of a transistor (when a gate insulating film thickness is used as a parameter) in the case where the deposited quantity of hafnium is 1×10¹⁴ [atoms/cm²];

FIG. 7 is a plan view showing a structure of functional blocks provided on an SoC semiconductor chip according an embodiment of the present invention;

FIGS. 8A to 8C each show a schematic plan view and a cross-sectional view of a typical transistor which is formed on the SoC semiconductor chip according to the embodiment of the present invention;

FIG. 9 is a table showing channel doses (hafnium deposition: deposited or not deposited) corresponding to three threshold voltages of a core transistor, and channel doses (hafnium deposition: deposited) corresponding to one threshold voltage of each of I/O transistors having power supply voltages of 1.8 V and 3.3 V, respectively;

FIG. 10 is a table showing threshold voltages required for transistors constituting the SoC according to the embodiment of the present invention, quantities of hafnium (Hf) to be deposited on a surface of the gate insulating film of each of the transistors, and channel doses with respect to the transistors;

FIG. 11A to 11D are cross-sectional diagrams showing a manufacturing process flow of the semiconductor device according to the embodiment of the present invention;

FIG. 12A to 12C are cross-sectional diagrams showing the manufacturing process flow of the semiconductor device according to the embodiment of the present invention;

FIG. 13A to 13D are cross-sectional diagrams showing the manufacturing process flow of the semiconductor device according to the embodiment of the present invention; and

FIGS. 14A and 14B are cross-sectional diagrams showing the manufacturing process flow of the semiconductor device according to the embodiment of the present invention.

### DETAILED DESCRIPTION OF THE PREFERRED EMBODIMENTS

Hereinafter, an embodiment of the present invention will be described in detail with reference to the drawings and tables.

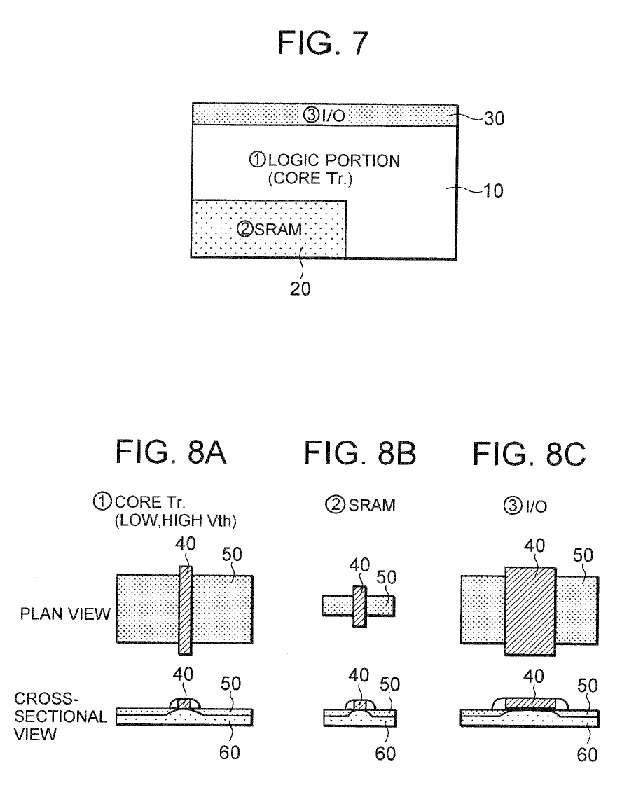

FIG. 7 shows a structure of functional blocks provided on an SoC semiconductor chip according to the embodiment of the present invention. The SoC includes a logic portion 10 including a plurality of logic transistors, an SRAM 20 including a plurality of memory cell transistors and peripheral transistors, and an I/O 30 including a plurality of I/O transistors. In the SoC, a plurality of power supply voltages are used. For example, the power supply voltage of each of the logic portion 10 and the SRAM 20 is 1.2 V, and the power supply voltage of the I/O 30 is 1.8 V and 3.3 V.

FIGS. 8A to 8C each show a schematic plan view and a cross-sectional view of a typical transistor which is formed on the SoC. FIG. 8A shows a logic transistor (also referred to as “core transistor”) which is used in the logic portion 10, is formed on a semiconductor substrate 60, and includes a diffusion layer 50 and a gate electrode 40. FIG. 8B shows a memory cell transistor which is formed on the semiconductor substrate 60 and includes the diffusion layer 50 and the gate electrode 40. FIG. 8C shows an I/O transistor which is formed on the semiconductor substrate 60 and includes the diffusion layer 50 and the gate electrode 40. The core transistors are each formed with substantially the same channel width, channel length, and gate insulating film thickness. As described above, transistors having three types of threshold voltages, that is, a high voltage, an intermediate voltage, and a low voltage, are prepared. Target threshold voltages of N-channel transistors are 0.30 V, 0.39 V, and 0.48 V, and target threshold voltages of P-channel transistors are −0.30 V, −0.39 V, and −0.48 V. The channel length and the gate insulating film thickness of the memory cell transistor are equal to those of the core transistor, but the channel width of the memory cell transistor is considerably small for achievement of higher density. The memory cell transistor is formed with a small channel width, but has a target threshold voltage (0.39 V) which is similar to the “intermediate” threshold voltage of the core transistor. Further, a memory cell transistor (not shown) having the “high” threshold voltage (0.48 V) is also prepared. The I/O transistor is formed with substantially the same channel width as that of the core transistor. However, the I/O transistor has two kinds of power supply voltages, that is, a 1.8 V system and a 3.3 V system, and is formed with a large channel length and a large gate insulating film thickness. Note that the I/O transistor of the 1.8 V system (hereinafter, referred to as “1.8 V I/O transistor”) has a gate insulating film thickness of 3.0 nm, and the I/O transistor of the 3.3 V system (hereinafter, referred to as “3.3V I/O transistor”) has a gate insulating film thickness of 7.0 nm. The threshold voltage of each of the both transistors is 0.5 V, which is larger than that of the core transistor or the memory cell transistor.

With respect to the transistors which are required to have a plurality of kinds of structures and a plurality of kinds of threshold voltages, threshold voltage control according to the present invention is to be performed in the following manner.

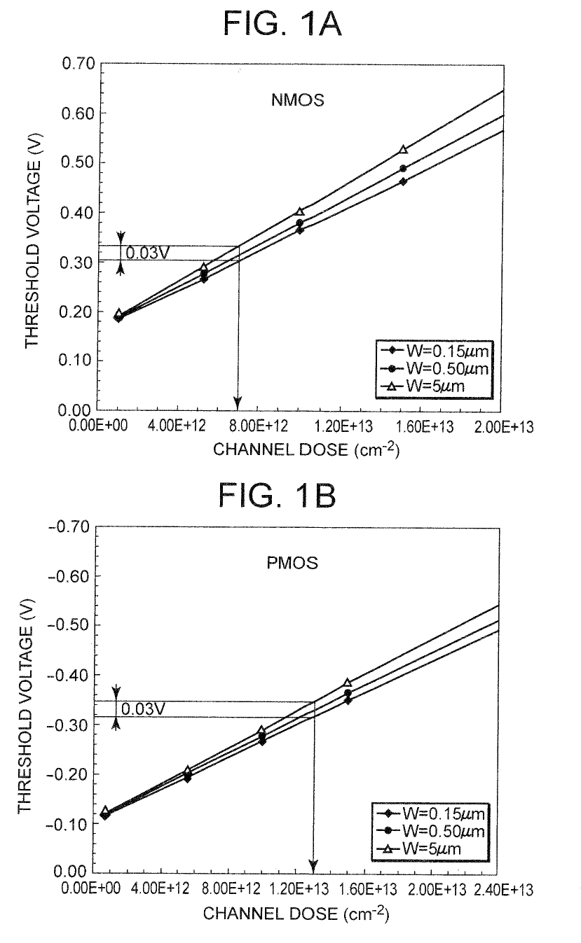

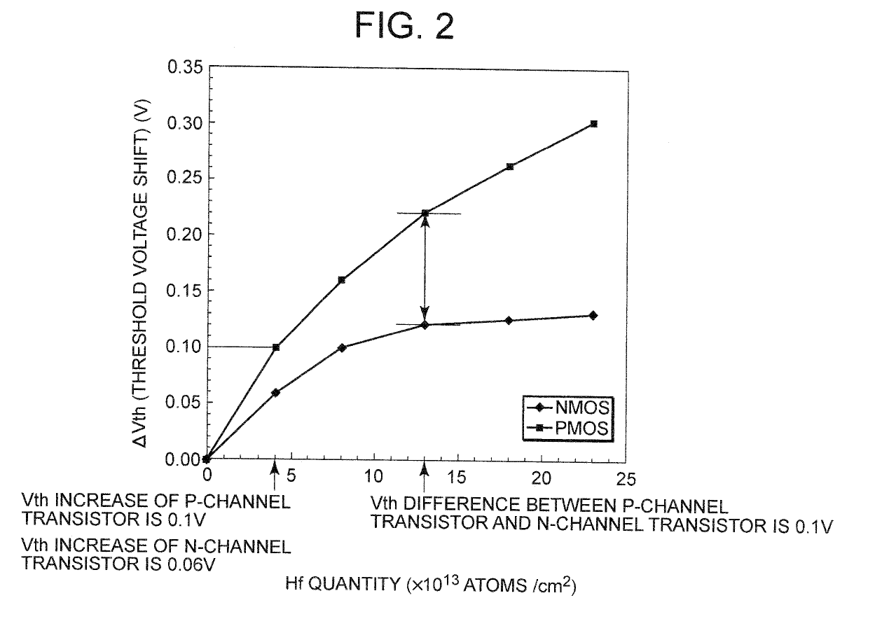

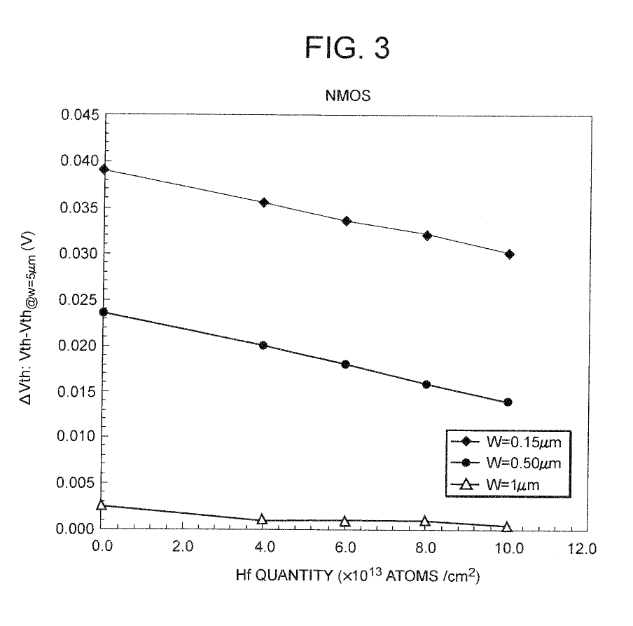

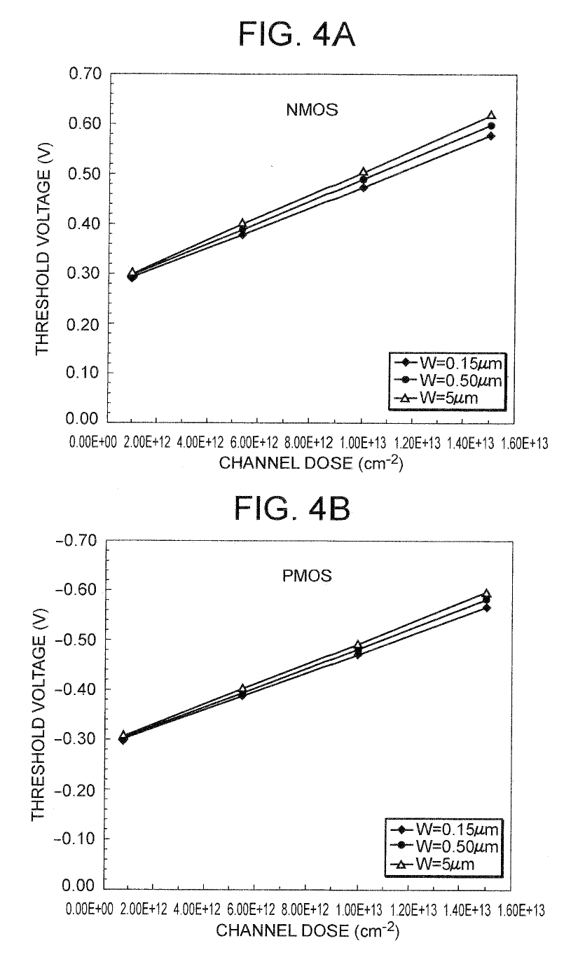

First, an increase amount of a threshold voltage according to work function control is determined. In the case of the embodiment, work function control is performed using hafnium to be deposited on the gate insulating film as shown in FIG. 2, and the quantity of hafnium to be deposited is determined with a transistor which is required to have a smallest threshold voltage being as a reference. In this case, the smallest threshold voltage is 0.3 V which is the threshold voltage of a core transistor for high-speed operation. As described above, an impurity concentration in a well region, in which the core transistor for high-speed operation is to be formed, is determined by placing priority on a junction capacitance and a resistance to high voltage. Accordingly, the impurity concentration on a surface of the well region becomes small, so it is necessary to perform channel doping. It is necessary to determine a necessary doping amount in consideration of a balance with the threshold voltage increase based on the deposited quantity of hafnium. Also in consideration of setting of the impurity concentration on the surface of the well region with high controllability, in the case of the core-transistor for high-speed operation, a channel dose for an N-channel transistor is set to 1×10¹² (atoms/cm²) and a channel dose for a P-channel transistor is set to 7×10¹¹ (atoms/cm²). As apparent from FIGS. 1A and 1B, the threshold voltage of the N-channel transistor is 0.19 V and the threshold voltage of the P-channel transistor is −0.12 V. As a result, the deposited quantity of hafnium is 1×10¹⁴ (atoms/cm²), and thus, the threshold voltage of the N-channel transistor is shifted by about 0.11 V. A variation of the threshold voltage of the P-channel transistor with that deposited quantity is about 0.18 V. As a result, the threshold voltages of the N-channel transistor and the P-channel transistor are 0.3 V and −0.3 V, respectively, which satisfy the target threshold voltages.

The increase amount of the threshold voltages based on the work function control using hafnium is 0.11 V in the case of the N-channel transistor, and is −0.18 V in the case of the P-channel transistor. As a result, the threshold voltages are increased by the amount of absolute values of the threshold voltages of all the transistors. In the case of using the threshold voltage control using hafnium, the channel dose necessary for each of the core transistor and the memory transistor which have an intermediate threshold voltage of 0.39 V is 5.3×10¹² (atmos/cm²) in the case of the N-channel transistor, and is 5.5×10¹² (atmos/m²) in the case of the P-channel transistor as is apparent from FIGS. 1A and 1B. The channel dose for a core transistor with a low leak current, that is, a transistor having a threshold voltage as high as 0.48 V, is 1.0×10¹³ (atoms/cm²) in the case of the N-channel transistor, and is 1.0×10¹³ (atoms/cm²) in the case of the P-channel transistor.

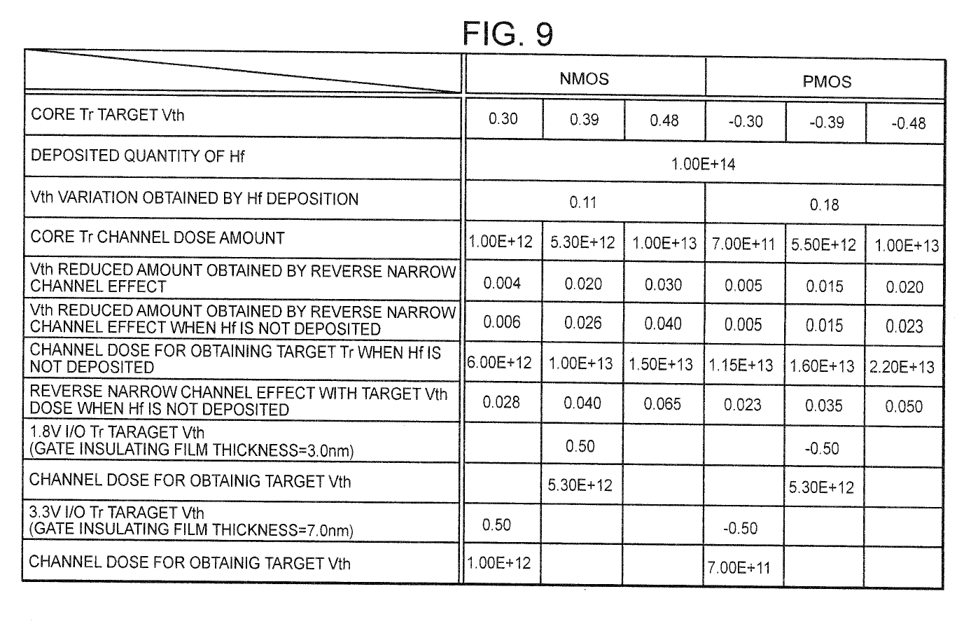

FIG. 9 shows channel doses and reduced amounts of threshold voltages (difference between a threshold voltage of a transistor having the width W of 5 μm and a transistor having the width W of 0.15 μm) obtained by channel doses and the reverse narrow channel effect, in a case where the work function control using hafnium is performed, and channel doses and reduced amounts of threshold voltages obtained by the reverse narrow channel effect in a case where the work function control using hafnium is not performed, with respect to three threshold voltage targets. In the case of the N-type transistor, when the work function control using hafnium is performed, as compared with the case where the work function control using hafnium is not performed, the channel dose can be reduced to 4.0×10¹² to 5.0×10¹² (atoms/cm²). In addition, when the threshold voltage is 0.48V, the reduced amount of the threshold voltage obtained by the reverse narrow channel effect is 0.065 V in the case where the work function control using hafnium is not performed, whereas, in the case where the work function control using hafnium is performed, the threshold voltage can be reduced to 0.03 V. In the case of the P-channel transistor, when the work function control using hafnium is performed, as compared with the case where the work function control using hafnium is not performed, the channel dose can be reduced to 4.5×10¹² to 11.0×10¹² (atoms/cm²). In addition, when the threshold voltage is 0.48 V, the reduced amount of the threshold voltage obtained by the reverse narrow channel effect is 0.005 V in the case where the work function control using hafnium is not performed, whereas, in the case where the work function control using hafnium is performed, the threshold voltage can be reduced to 0.020 V.

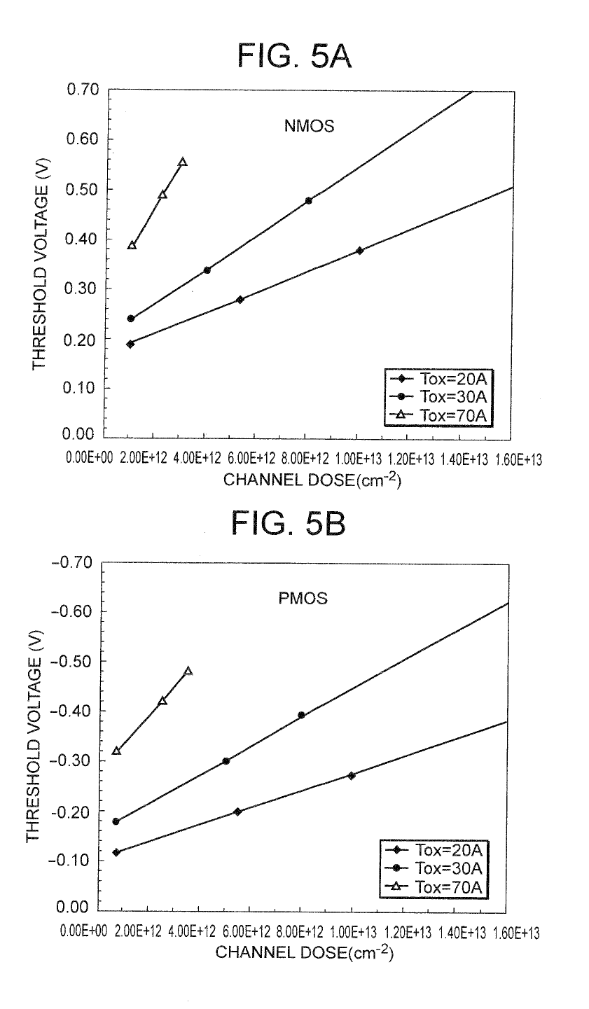

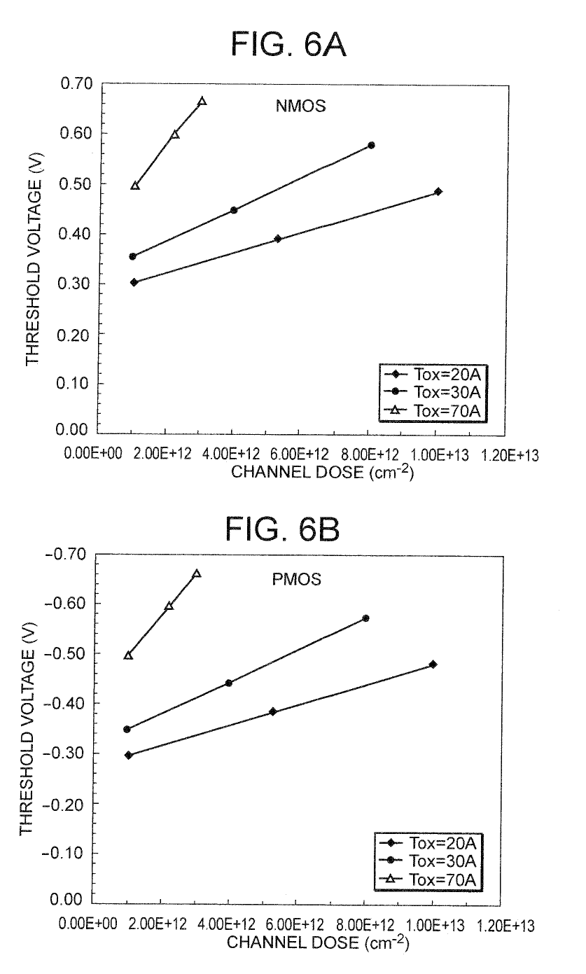

The threshold voltage necessary for the I/O transistor is 0.5 V. In a case of the 1.8 I/O transistor having a gate insulating film thickness of 3.0 nm, by using a deposited quantity of hafnium (1.0×10¹⁴ (atoms/cm²)) which is equal to that of the core transistor, and by using a channel dose for obtaining a threshold voltage of 0.39 V which is equal to that of the core transistor, the threshold voltage is increased by 0.11 V, which corresponds to the amount of the increased thickness of the gate insulating film, thereby obtaining a threshold voltage of 0.50 V as shown in FIGS. 5A and 5B.

The 3.3 V I/O transistor has a gate insulating film thickness of 7.0 nm. In this case, by using a deposited quantity (1.0×10¹⁴ (atoms/cm²)) which is equal to that of the core transistor, and by using a channel dose for obtaining the threshold voltage of 0.30 V which is equal to that of the core transistor, the threshold voltage is increased by 0.20 V, which corresponds to the amount of the increased thickness of the gate insulating film, thereby obtaining the threshold voltage of 0.50 V as shown in FIGS. 5A and 5B.

The target threshold voltages and the channel doses of those I/O transistors are also shown in FIG. 9.

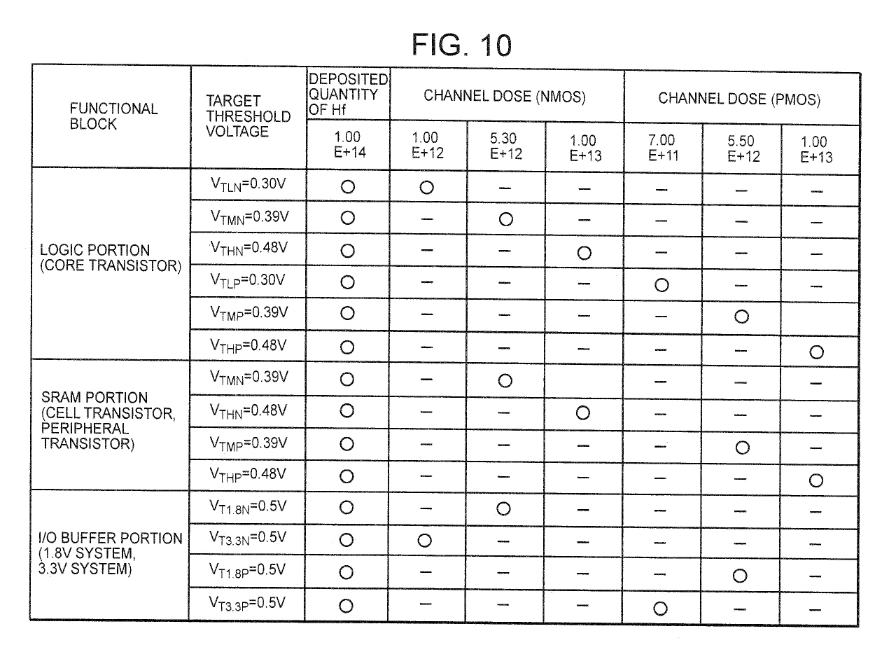

In this manner, the deposited quantity of hafnium and the necessary channel dose are determined, and in addition, transistors which can share the channel dope can be specified. Specifically, the threshold voltage necessary for each transistor constituting the SoC according to the embodiment, the quantity of hafnium (Hf) to be deposited on the surface of the gate insulating film of each transistor, and the channel dose for each transistor are collectively shown in FIG. 10.

All the transistors have the same Hf quantity. There are three kinds of channel doses for the N-channel transistor. Of those channel doses, a channel dose of 1.0×10¹² (atoms/cm²) is shared by a core transistor having a low threshold voltage (VTLN=0.30 V) and a 3.3 V I/O transistor (VT3.3N=0.30 V), a channel dose of 5.3×10¹² (atoms/cm²) is shared by a core transistor and a memory transistor, which have an intermediate threshold voltage (VTMN=0.39 V), and by a 1.8 V I/O transistor (VT1.8N=0.30 V), and a channel dose of 1.0×10¹³ (atoms/cm²) is shared by a core transistor and a memory transistor which have a high threshold voltage (VTHN=0.48 V). There are also three kinds of channel doses for the P-channel transistor. Of those channel doses, a channel dose of 7.0×10¹¹ (atoms/cm²) is shared by a core transistor having a low threshold voltage (VTLN=−0.30 V) and a 3.3 V I/O transistor (VT3.3P=−0.30 V), a channel dose of 5.5×10¹² (atoms/cm²) is shared by a core transistor and a memory transistor, which have an intermediate threshold voltage (VTMP=−0.39 V), and by a 1.8 VI/O transistor (VT1.8P=−0.50 V), and a channel dose of 1.0×10¹³ (atoms/cm²) is shared by a core transistor and a memory transistor which have a high threshold voltage (VTHP=−0.48 V).

Hereinafter, a flow of manufacturing an SoC using a manufacture parameter determined in the above-mentioned manner will be described in detail with reference to the drawings.

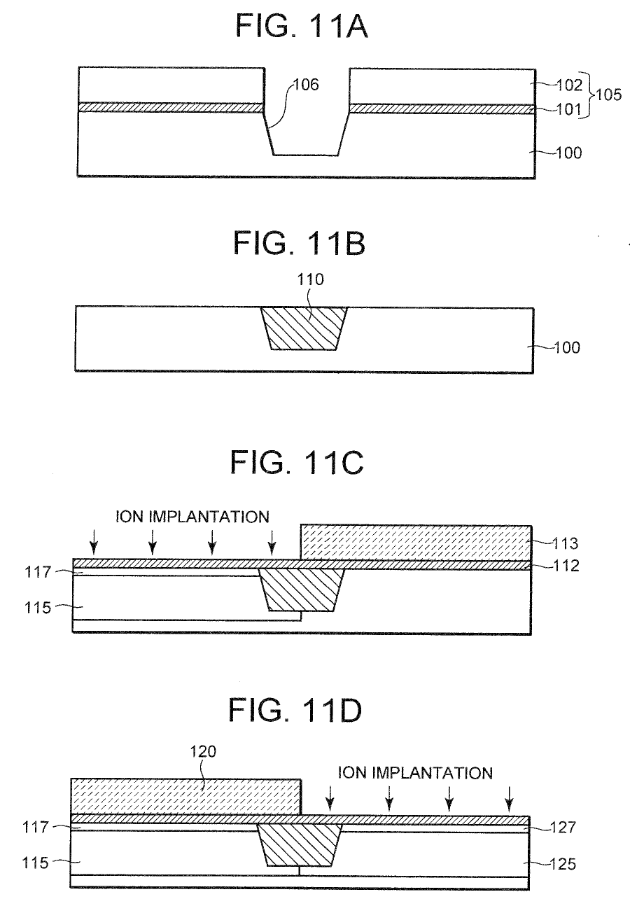

FIG. 11A to FIG. 14B are cross-sectional diagrams for explaining a manufacturing process flow process showing an outline from an element isolation process with respect to a silicon substrate which is used as a semiconductor substrate, to formation of electrodes of transistors. In each figure, only one N-channel transistor and one P-channel transistor are shown. However, it should be noted that, actually, a plurality of transistors are formed on the same silicon substrate with a necessary gate width and length and a necessary gate insulating film thickness. It is easy for understanding to show all the 14 kinds of transistors shown in FIG. 10, but only the core transistor with the low threshold voltage is representatively shown in FIGS. 11A to 14B, and the other kinds of transistors are described if necessary, for simplification of the description of the drawings.

As shown in FIG. 11A, on a silicon substrate 100, an element isolating insulating film 105 including an oxide film 101 and a nitride film 102 is formed. A portion corresponding to an element isolation region of the insulating film 105 is selectively removed, and the substrate 100 is subjected to etching with the remaining insulating film being used as a mask, thereby forming an element isolating trench 106.

The trench 106 is filled with an insulating film such as a silicon oxide film, and is subjected to chemical mechanical polishing (CMP), thereby forming an element isolating insulating film 110 as shown in FIG. 11B. As a result, an element forming region, in which the transistors are to be formed, is isolated by so-called shallow trench isolation (STI).

On the entire surface of the substrate 100 having the element isolating insulating film 110 obtained by STI, as shown in FIG. 11C, a sacrificial oxide film 112 and a photoresist film 113 are formed, and the photoresist film 113 is subjected to a selective etching process. As shown in FIG. 10, the portion to be removed is a portion corresponding to the element forming region in which the N-channel core transistor having the low threshold voltage and the N-channel 3.3 V I/O transistor are to be formed. After that, with the remaining photoresist film 113 being used as a mask, ion implantation with a boron impurity is performed so as to form a P-well region 115. In addition, ion implantation with a boron impurity (i.e., channel doping) is performed with the dose shown in FIG. 10 so as to form a channel dope region 117.

The photoresist film 113 is removed, and a new photoresist film (not shown) is selectively formed. Portions which are not covered with the new photoresist film correspond to an element forming region in which intermediate-threshold voltage N-channel core and memory transistors are to be formed, and to an element forming region in which the N-channel 1.8 V I/O transistor is to be formed. With the photoresist film being used as a mask, ion implantation for the P-well region and the channel dope region is performed with respect to those transistors. This process flow is carried out again, and with respect to an element forming region in which high-threshold voltage N-channel core and memory transistors are to be formed, ion implantation for the P-well region and the channel dope region is performed.

Next, as shown in FIG. 11D, a photoresist film 120 is coated and formed again, and the portion corresponding to an element forming region in which the low-threshold voltage P-channel core transistor and the P-channel 3.3V I/O transistor are to be formed is removed. Then, ion implantation with a phosphorus impurity is performed so as to form an N-well region 125, and ion implantation with an arsenic impurity is performed so as to form a channel dope region 127. The channel dose shown in FIG. 10 is used.

After that, the photoresist film 120 is removed, ion implantation (not shown) for forming well regions and channel dope regions of intermediate-threshold voltage P-channel core and memory transistors and of a P-channel 1.8 V I/O transistor is performed by selectively forming a new photo resist film. Then, ion implantation for well regions and channel dope regions of high-threshold voltage P-channel core and memory transistors is performed by selectively forming a new photoresist film.

Thus, the ion implantation for the well regions and the channel dope regions necessary for the transistors is completed. In this case, the number of times of the mask forming process for the ion implantation, which is actually carried out with respect to 14 kinds of transistors, is reduced to 6, which is a half of the conventional case, and thus the number of manufacturing processes is reduced to a large extent.

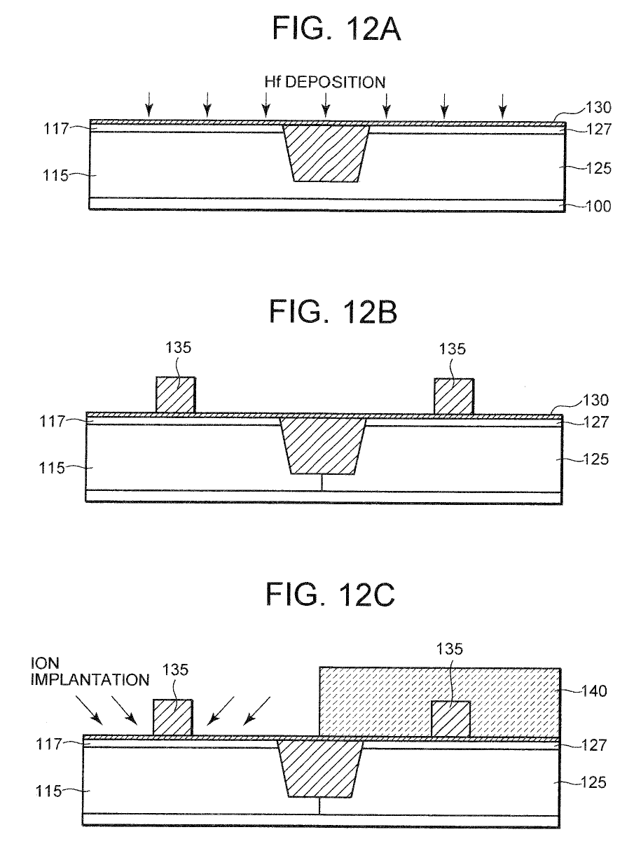

After that, the surface of the substrate 100 is subjected to cleaning, and as shown in FIG. 12A, a gate insulating film 130 is formed on the entire surface with a thickness of 2.0 nm. The gate insulating film thicknesses of the 1.8 V I/O transistor and the 3.3V I/O transistor are 2.0 nm and 7.0 nm, respectively. With regard to those transistors, after execution of the mask process with respect to the core and memory transistors, the gate insulating film is regrown. A silicon oxide nitride film is used as the gate insulating film. Accordingly, a silicon oxide film is first formed on the surface of the substrate 100 by thermal oxidation, and then a plasma nitriding process is performed. Thus, the gate insulating film necessary for each transistor is formed.

After that, according to the present invention, hafnium is deposited on the entire surface of the gate insulating film with a quantity as shown in FIG. 9 by atomic layer deposition (ALD) (FIG. 12A). The deposition may be carried out by a CVD method or a sputtering method.

A polysilicon layer is formed by CVD on the entire surface of the gate insulating film to which hafnium is deposited, and patterning is performed, thereby forming silicon gate electrodes 135 for each transistor (FIG. 12B). Thus, in the embodiment, the threshold voltage increase by the deposition of hafnium to the gate insulating film is used for the work function control based on the gate structure.

Next, a source/drain region forming process for each transistor is to be performed. In the embodiment, in order to perform fine adjustment of the threshold voltage of each transistor, selective ion implantation into the channel region is further performed with impurities presenting the same conductive type as that of a channel dope region 117, which is so-called pocket implantation.

In other words, as described above, the threshold voltage of each transistor is controlled mainly based on the channel dose and the quantity of hafnium deposited on the gate insulating film, but actually, it is inevitable that the dose and the deposited quantity vary. In addition, a combination of the channel dose and the deposited quantity of hafnium for obtaining a desired threshold voltage cannot be precisely determined in some cases. Accordingly, the threshold voltage is finely adjusted by pocket implantation. The implantation amount is generally obtained by feedback from experiences or prototypes.

In the pocket implantation, as shown in FIG. 12C, the forming region of each P-channel transistor is covered with a photoresist film 140 as a mask, and ion implantation is performed using boron as impurities into the well region 115 from an oblique direction. In the embodiment, the N-channel I/O transistor is also covered with a mask (not shown). Specifically, the pocket implantation for the core and memory transistors is performed with the same quantity, but fine adjustment of the threshold voltage with respect to each I/O transistor is performed in a little different manner, thereby varying the amount of pocket implantation for each transistor.

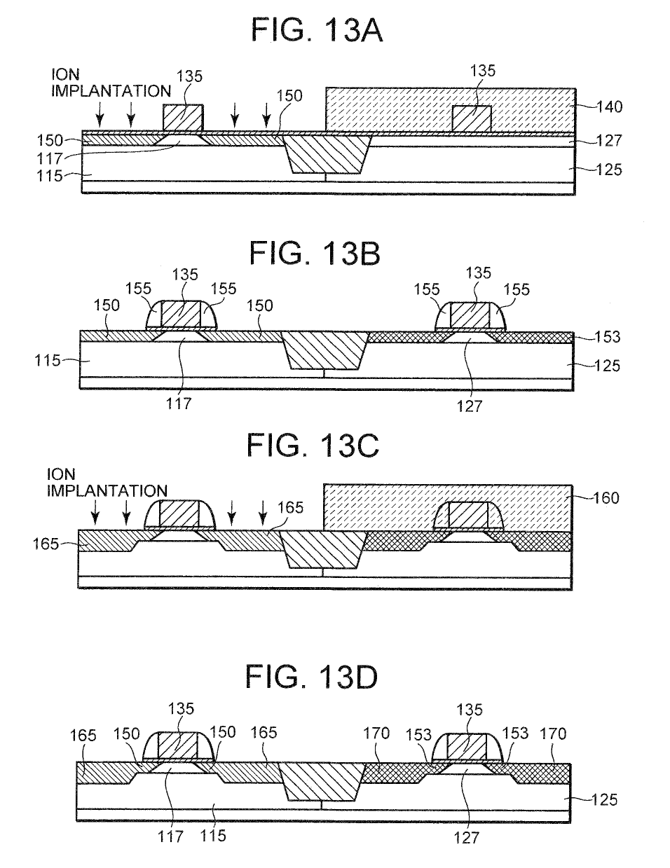

After execution of the pocket implantation, as shown in FIG. 13A, by using the photoresist film 140 as a mask again, ion implantation with arsenic is performed, and a source/drain extension region 150 of each of the N-channel core and memory transistors is formed. After that, the resist film 140 is removed, a new resist film is selectively formed to form a mask layer, and pocket implantation and source/drain extension region formation for each I/O transistor are performed (not shown).

After that, as shown in FIG. 13B, the N-channel transistor is covered with a mask layer (not shown), and pocket implantation and formation of a source/drain extension region 153 are performed with respect to the P-channel core transistor, memory transistor, and I/O transistor in the same manner as described with reference to FIG. 13A. Then, on a side surface of the gate of each transistor, a side wall insulating film 155 is formed.

As a matter of course, when it is unnecessary to perform fine adjustment of the threshold voltage by pocket implantation, the pocket implantation is omitted. Alternatively, fine adjustment of the threshold voltage by pocket implantation may be performed only for a part of transistors.

As shown in FIG. 13C, a photoresist film 160 is formed as a mask layer so as to cover the forming region of each P-channel transistor, and ion implantation with arsenic is performed, to thereby an N-type source/drain region 165 of each N-channel transistor. The formation process is performed with respect to the core transistor, the memory transistor, and the I/O transistor at the same time.

For the source/drain region of each P-channel transistor, as shown in FIG. 13D, each N-channel transistor is covered with the mask layer, and ion plantation with boron is performed (not shown), to thereby form a P-type source/drain region 170.

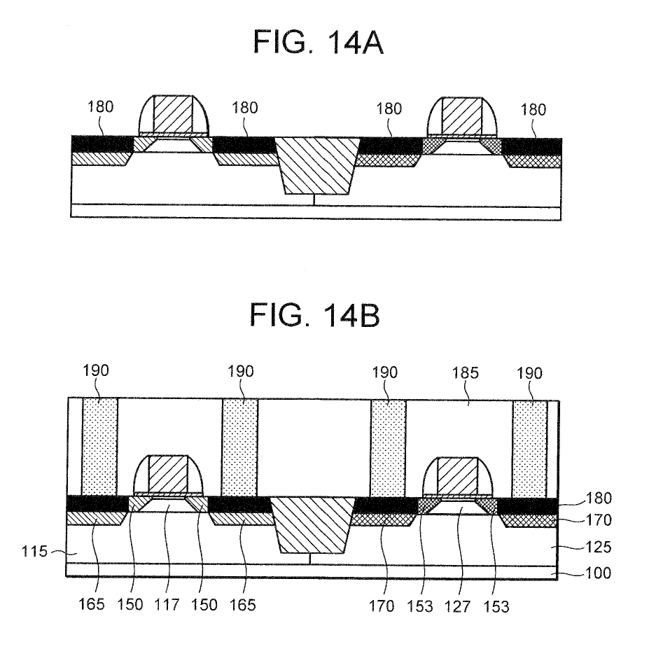

After that, as shown in FIG. 14A, a desired metal such as titanium, cobalt, or nickel is deposited on the entire surface, and heat treatment is performed to thereby form a metal silicide layer 180 on the surfaces of the source/drain regions 165 and 170 of each transistor. Note that, the silicide layer may be formed on the surface of polysilicon gate electrode (not shown).

Then, as shown in FIG. 14B, an interlayer insulating film 185 such as a silicon oxide film is formed on the entire surface, and a contact hole for each transistor is opened, and a metal contact plug electrode 190 is formed on tungsten or the like.

As described above, the SoC which includes: transistors each having a different gate width, the same gate insulating film thickness, and substantially the same threshold voltage; transistors each having the same gate width, the same gate insulating film thickness, and a different threshold voltage; and transistors each having a threshold voltage corresponding to a insulating film difference, is produced with a smaller number of processes.

Note that, in the embodiment, the deposition of hafnium (Hf) to the gate insulating film is used for the threshold voltage control method using the work function control based on the gate structure. As a metal to be used, not only Hf, but also one of or a combination of a plurality of Zr, Al, La, Pr, Y, Ti, Ta, and W may be used. Further, in addition to the control method using only the deposition of the metal, a work function control method capable of obtaining the same effects may be employed. For example, when an HfSiON film is used as the gate insulating film and an Ni₃Si of full silicide is used as the gate electrode material, a threshold voltage increase of about 0.3V is obtained. When NiSi₂ of full silicide is used as the gate electrode material of the P-channel transistor, a threshold voltage shift of about −0.35 V is obtained. When an HfSiON film is used as the gate insulating film and TaSiN of full silicide is used as the gate electrode material of the N-channel transistor, a threshold voltage increase of about 0.35 V is obtained. When TiSiN of full silicide is used as the gate electrode material of the P-channel transistor, a threshold voltage shift of about −0.35 V is obtained. In addition, the work function control only by the gate electrode may be performed without depositing the metal on the gate insulating film. For example, when an NiSi electrode is formed by employment of a full silicide process in which phosphorus of 5.0×10¹⁵ (atoms/cm²) is implanted into a gate polysilicon electrode of the N-channel transistor, and then Ni is deposited thereon, and heat treatment is performed to fully silicide the entire gate electrode, the threshold voltage is increased by about 0.3 V. When boron of 5.0×10¹⁵ (atoms/cm²) is implanted into the gate polysilicon electrode of the P-channel transistor, and then the NiSi electrode is formed by the full silicide process, the threshold voltage is shifted by about −0.4 V.

Although the present invention has been described above in connection with several preferred embodiments thereof, it is apparent that the present invention is not limited to the above embodiments, and may be modified and changed without departing from the scope and spirit of the invention.

What is claimed is:

1. A semiconductor device comprising a plurality of transistors formed in a semiconductor substrate, the transistors including first and second transistors that are different in channel width from each other, the first and second transistors having respective channel regions doped with impurities by amounts that are substantially equal to each other and further having respective gate structures that provide predetermined work functions respectively to the first and second transistors, the first and second transistors being thereby approximately equal in threshold voltage to each other irrespective of the first transistor being different in channel width from the second transistor.

2. A semiconductor device according to claim 1, wherein the gate structure of each of the first and second transistors comprises at least one of deposition of a metal other than a gate electrode on a gate insulating film and formation of a gate electrode by a metal.

3. A semiconductor device according to claim 1, wherein a range in which the first and second transistors is approximately equal in threshold voltage to each other is equal to or smaller than 0.03 V.

4. A semiconductor device according to claim 1, wherein each of the first and second transistors is of an N-channel type and the amount of the impurities doped into the channel region of each of the first and second transistors is not more than 1.1×10¹³ atoms/cm².

5. A semiconductor device according to claim 1, wherein each of the first and second transistors is of a P-channel type and the amount of the impurities doped into the channel region of each of the first and second transistors is not more than 1.4×10¹³ atoms/cm².

6. A semiconductor device according to claim 1, wherein each of the first and second transistors is of an N-channel type and the plurality of transistors further includes third and fourth transistors that are different in channel width from each other, each of third and fourth transistors being of a P-channel type, the third and fourth transistors having respective channel regions doped with impurities by amounts that are substantially equal to each other and further having respective gate structures that provide predetermined work functions respectively to the third and fourth transistors, third and fourth transistors being thereby approximately equal in threshold voltage to each other irrespective of the third transistor being different in channel width from the fourth transistor, the amount of the impurities doped into the channel region of each of the first and second transistors is not more than 1.1×10¹³ atoms/cm², and the amount of the impurities doped into the channel region of each of the third and fourth transistors is not more than 1.4×10¹³ atoms/cm².

7. A semiconductor device according to claim 6, wherein the metal deposited on the gate insulating film is selected from the group consisting of Hf, Zr, Al, La, Pr, Y, Ti, Ta, and W; and an amount of the metal to be deposited is 4×10¹³ to 1.3×10¹⁴ atoms/cm².

8. A semiconductor device, comprising:
a logic functional block including a first core transistor; and
a memory functional block including a first memory transistor, wherein:
each of the first core transistor and the first memory transistor is subject in threshold voltage to a work function control of a gate structure cased by at least one of deposition of a metal other than a gate electrode on a gate insulating film and formation of a gate electrode by a metal; and
the first core transistor and the first memory transistor are substantially the same as each other in a Gate Induced Drain Leakage (GIDL) characteristic.

9. A semiconductor device according to claim 8, further comprising an I/O functional block including a first I/O transistor which is different in thickness of a gate insulating film from each of the first core transistor and the first memory transistor, the first I/O transistor is subject in threshold voltage to a work function control of a gate structure cased by at least one of deposition of a metal other than a gate electrode on a gate insulating film and formation of a gate electrode by a metal and is substantially the same in the GIDL characteristic as each of the first core transistor and the first memory transistor.

10. A semiconductor device according to claim 8, wherein the logic functional block further includes a second core transistor; the second core transistor being is subject in threshold voltage to a work function control of a gate structure cased by at least one of deposition of a metal other than a gate electrode on a gate insulating film and formation of a gate electrode by a metal and is different in the GIDL characteristic from the first core transistor.

11. A semiconductor device according to claim 10, wherein each of the first core transistor and the second core transistor is larger in channel width than the first memory transistor.

12. A semiconductor device according to claim 9, wherein the first I/O transistor is larger in thickness of a gate insulating film than each of the first core transistor and the first memory transistor.

13. A method of manufacturing a semiconductor device including a first transistor having a first channel width and a second transistor having a second channel width different from the first channel width,
the method of manufacturing a semiconductor device comprising:
forming the first transistor and the second transistor, wherein said forming the first transistor and the second transistor includes:
implanting substantially same quantity of impurities into a channel region of each of the first transistor and the second transistor; and
forming a gate structure for each of the first transistor and the second transistor, said gate structure fulfilling threshold voltage control according to work function control with respect to the channel region of each of the first transistor and the second transistor.

14. A method of manufacturing a semiconductor device according to claim 13, wherein said forming the gate structure comprises at least one of forming a silicon gate electrode after depositing a predetermined metal on a gate insulating film of each of the first transistor and the second transistor, and forming a metal gate electrode containing a full silicide gate electrode on the gate insulating film of each of the first transistor and the second transistor.

15. A method of manufacturing a semiconductor device according to claim 13, wherein
the semiconductor device further includes a third transistor having a gate insulating film thickness different from that of each of the first transistor and the second transistor, the method of manufacturing a semiconductor device further comprises:
forming the third transistor,
wherein said forming the third transistor includes:
implanting substantially same quantity of impurities into a channel region of the third transistor as that for any of the first transistor and the second transistor;
forming a gate insulating film having a desired thickness; and
forming a gate structure fulfilling the threshold voltage control according to the work function control.

16. A method of manufacturing a semiconductor device according to claim 13, wherein
the semiconductor device further includes a fourth transistor having a channel width substantially equal to that of the first transistor and having a threshold voltage different from that of the first transistor, the method of manufacturing a semiconductor device further comprises:
forming the fourth transistor,
wherein said forming the fourth transistor including:
implanting quantity of impurities different from that for the first transistor into a channel region of the fourth transistor; and
forming a gate structure fulfilling the threshold voltage control according to the work function control.

17. A method of manufacturing a semiconductor device including a logic functional block having a first transistor, a second transistor, and a third transistor, a memory functional block having a fourth transistor, and an I/O block having a fifth transistor, the method of manufacturing a semiconductor device comprising:
performing channel doping with respect to the first transistor and the fifth transistor with a first dose;
performing channel doping with respect to the second transistor and the fourth transistor with a second dose;
performing channel doping with respect to the third transistor with a third dose;
forming a gate insulating film of each of the first transistor, the second transistor, the third transistor, and the fourth transistor with a first thickness;
forming a gate insulating film of the fifth transistor with a second thickness different from said first thickness; and
forming a gate structure of each of the first transistor, the second transistor, the third transistor, the fourth transistor, and the fifth transistor, through at least one of forming a silicon gate electrode by depositing a predetermined metal on the gate insulating films, and forming a metal gate electrode containing a full silicide gate electrode on the gate insulating films.

18. A method of manufacturing a semiconductor device according to claim 17, wherein:
the memory functional block further includes a sixth transistor;
the I/O block further includes a seventh transistor; and
the method of manufacturing a semiconductor device further comprises:
performing channel doping with respect to the fourth transistor with the third dose;
performing channel doping with respect to the seventh transistor with the second dose;
forming a gate insulating film of the sixth transistor with the first thickness;
forming a gate insulating film of the seventh transistor with the third thickness; and
forming a gate structure of each of the sixth transistor and the seventh transistor through at least one of forming a silicon gate electrode by depositing a predetermined metal on the gate insulating films, and forming a metal gate electrode containing a full silicide gate electrode on the gate insulating films.

19. A method of manufacturing a semiconductor device according to claim 18, wherein:
the first transistor, the second transistor, the third transistor, the fourth transistor, and the sixth transistor have a substantially same first threshold voltage; and
the fifth transistor and the seventh transistor have a substantially same second threshold voltage different from said first threshold voltage.
